(19) United States
(12) Patent Application Publication
(10) Pub. No.: US 2023/0395420 A1
(43) Pub. Date: Dec. 7, 2023

(54) FILM ADHESIVE AND METHOD FOR MAKING SAME; DICING/DIE BONDING INTEGRATED FILM AND METHOD FOR MAKING SAME; AND SEMICONDUCTOR DEVICE AND METHOD FOR MAKING SAME

(71) Applicant: SHOWA DENKO MATERIALS CO., LTD., Tokyo (JP)

(72) Inventors: Yuya AKIYAMA, Minato-ku, Tokyo (JP); Kohei TANIGUCHI, Minato-ku, Tokyo (JP); Yuya HIRAMOTO, Minato-ku, Tokyo (JP); Megumi KAMONO, Minato-ku, Tokyo (JP); Kei ITAGAKI, Minato-ku, Tokyo (JP)

(21) Appl. No.: 18/258,846

(22) PCT Filed: Dec. 25, 2020
(86) PCT No.: PCT/JP2020/048914

§ 371 Date: Jun. 22, 2023

(51) Int. Cl. H01L 21/683; C08L 61/04; H01L 21/52; C09J 161/04; C09J 7/28; H01L 23/14; C09J 163/00

(52) U.S. Cl. CPC H01L 21/6836; C08L 61/04; H01L 21/52; C09J 161/04; C09J 7/28; H01L 23/14; C09J 163/00; H01L 2221/68327

(57) ABSTRACT

The present disclosure provides a semiconductor device. The semiconductor device includes a semiconductor chip; a support member having the semiconductor chip mounted thereon; and a bonding adhesive member provided between the semiconductor chip and the support member and adhering the semiconductor chip and the support member. The bonding adhesive member includes a sintered body of silver particles.

### TECHNICAL FIELD

The present disclosure relates to a film-shaped adhesive and a method for manufacturing the film-shaped adhesive, a dicing-die bonding integrated film and a method for manufacturing the dicing-die bonding integrated film, and a semiconductor device and a method for manufacturing the semiconductor device.

### BACKGROUND ART

Conventionally, a semiconductor device is manufactured through the following steps. First, a semiconductor wafer is stuck to an adhesive sheet for dicing, and while in that state, the semiconductor wafer is singulated into semiconductor chips (dicing step). Subsequently, a pickup step, a pressure-bonding step, a die bonding step, and the like are carried out. In Patent Literature 1, an adhesive film (dicing-die bonding integrated film) combining a function of fixing a semiconductor wafer in a dicing step and a function of adhering semiconductor chips to a substrate in a die bonding step, is disclosed. An adhesive piece-attached semiconductor chip can be obtained by singulating a semiconductor wafer and a bonding adhesive layer in the dicing step.

In recent years, devices called power semiconductor devices that perform control of electric power and the like have been popularized. Power semiconductor devices are likely to generate heat due to the electric current supplied thereto and are required to have excellent heat dissipation properties. In Patent Literature 2, a conductive film-shaped adhesive (film-shaped adhesive) having higher heat dissipation properties after curing compared with the heat dissipation properties before curing and a film-shaped adhesive-attached dicing tape (dicing-die bonding integrated film) are disclosed.

### CITATION LIST

### Patent Literature

Patent Literature 1: JP 2008-218571 A
Patent Literature 2: JP 2016-103524 A

### SUMMARY OF INVENTION

### Technical Problem

However, semiconductor devices manufactured using conventional film-shaped adhesives or dicing-die bonding integrated films do not have sufficient heat dissipation properties, and there is still room for improvement.

Thus, it is a main object of the present disclosure to provide a semiconductor device having excellent heat dissipation properties.

### Solution to Problem

The inventors of the present disclosure conducted an investigation so as to solve the above-described problems, and the inventors found that when a film-shaped adhesive obtainable by mixing, under predetermined temperature conditions, predetermined silver particles as a bonding adhesive member that adheres a semiconductor chip and a support member is used, the heat dissipation properties of the semiconductor device are improved. The inventors of the present disclosure further conducted an investigation in relation to this point, and the inventors found that silver particles are sintered to form a sintered body in a cured (C-stage) state after a curing treatment of the film-shaped adhesive, and that the formation of a sintered body in the bonding adhesive member has an influence on the improvement of thermal conductivity and on the improvement of heat dissipation properties, thus completing the invention of the present disclosure.

An aspect of the present disclosure relates to a semiconductor device. This semiconductor device includes: a semiconductor chip; a support member having the semiconductor chip mounted thereon; and a bonding adhesive member provided between the semiconductor chip and the support member and adhering the semiconductor chip and the support member. The bonding adhesive member includes a sintered body of silver particles. According to such a semiconductor device, since the bonding adhesive member exhibits a high thermal conductivity, the semiconductor device has excellent heat dissipation properties.

Another aspect of the present disclosure relates to a method for manufacturing a film-shaped adhesive. This method for manufacturing a film-shaped adhesive includes mixing a raw material varnish containing silver particles and an organic solvent under the temperature conditions of 50° C. or higher and preparing an adhesive varnish containing the silver particles, the organic solvent, and a thermosetting resin component; and forming a film-shaped adhesive by using the adhesive varnish. By using a film-shaped adhesive that is obtained by such a manufacturing method, a semiconductor device having excellent heat dissipation properties can be produced.

The silver particles may be silver particles manufactured by a reduction method or silver particles that are surface-treated by using a surface treatment agent.

A content of the silver particles may be 50% to 95% by mass based on a total solid content of the adhesive varnish.

The adhesive varnish may further contain an elastomer. The thermosetting resin component may include an epoxy resin and a phenol resin.

Another aspect of the present disclosure relates to a method for manufacturing a dicing-die bonding integrated film. This method for manufacturing a dicing-die bonding integrated film includes: preparing a film-shaped adhesive obtainable by the above-described manufacturing method and a dicing tape including a base material layer and a pressure-sensitive adhesive layer provided on the base material layer; and sticking together the film-shaped adhesive and the pressure-sensitive adhesive layer of the dicing tape to form a dicing-die bonding integrated film including the base material layer, the pressure-sensitive adhesive layer, and a bonding adhesive layer formed from the film-shaped adhesive, in this order. By using a dicing-die bonding integrated film obtainable by such a manufacturing method, a semiconductor device having excellent heat dissipation properties can be produced.

Another aspect of the present disclosure relates to a method for manufacturing a semiconductor device. This method for manufacturing a semiconductor device includes: sticking a semiconductor wafer to the bonding adhesive layer of the dicing-die bonding integrated film obtainable by the above-described manufacturing method; producing a plurality of singulated adhesive piece-attached semiconductor chips by dicing the semiconductor wafer with the bonding adhesive layer stuck thereto; adhering the adhesive piece-attached semiconductor chips on a support member, with the adhesive piece interposed therebetween; and thermally curing the adhesive piece in the adhesive piece-attached semiconductor chip adhered to the support member. A semiconductor device obtainable by such a manufacturing method has excellent heat dissipation properties since the bonding adhesive member exhibits a high thermal conductivity.

Another aspect of the present disclosure relates to a film-shaped adhesive. This film-shaped adhesive includes a sintered body of silver particles in a cured product obtainable when the film-shaped adhesive is thermally cured under the conditions of 170° C. and 3 hours. By using such a film-shaped adhesive, a semiconductor device having excellent heat dissipation properties can be produced. With regard to the film-shaped adhesive, the cured product obtainable when the film-shaped adhesive is thermally cured under the conditions of 170° C. and 3 hours may have a thermal conductivity of 5 W/m·K or higher.

A content of the silver particles may be 50% to 95% by mass based on a total amount of the film-shaped adhesive.

Another aspect of the present disclosure relates to a dicing-die bonding integrated film. This dicing-die bonding integrated film includes a base material layer, a pressure-sensitive adhesive layer, and a bonding adhesive layer formed from the above-described film-shaped adhesive, in this order. By using such a dicing-die bonding integrated film, a semiconductor device having excellent heat dissipation properties can be produced.

### Advantageous Effects of Invention

According to the present disclosure, a semiconductor device having excellent heat dissipation properties and a method for manufacturing the semiconductor device are provided. Furthermore, according to the present disclosure, a film-shaped adhesive that enables manufacture of a semiconductor device having excellent heat dissipation properties and a method for manufacturing the film-shaped adhesive, and a dicing-die bonding integrated film and a method for manufacturing the dicing-die bonding integrated film are provided.

### BRIEF DESCRIPTION OF DRAWINGS

FIG. 1 is a schematic cross-sectional view illustrating an embodiment of a semiconductor device.

FIG. 2 is a schematic cross-sectional view illustrating an embodiment of a film-shaped adhesive.

FIG. 3 is a schematic cross-sectional view illustrating an embodiment of a dicing-die bonding integrated film.

FIG. 4 is schematic cross-sectional views illustrating an embodiment of a method for manufacturing a semiconductor device. FIGS. 4(a), 4(b), 4(c), 4(d), 4(e), and 4(f) are cross-sectional views each schematically illustrating the step.

FIG. 5 is an image of a cross-section cut along the thickness direction of a film-shaped adhesive in the C-stage state of Example 1, which was photographed by using a scanning electron microscope (SEM).

### DESCRIPTION OF EMBODIMENTS

Hereinafter, embodiments of the present disclosure will be described with appropriate reference to the drawings. However, the present disclosure is not intended to be limited to the following embodiments. In the following embodiments, the constituent elements thereof (also including steps and the like) are not essential unless particularly stated otherwise. The sizes of constituent elements in each drawing are conceptual, and the relative relationship between the sizes of the constituent elements is not limited to that shown in each drawing.

In the present specification, a numerical value range indicated by using the term “to” represents a range including the numerical values described before and after the term “to” as the minimum value and the maximum value, respectively. With regard to a numerical value range described stepwise in the present specification, the upper limit value or lower limit value of a numerical value range of a certain stage may be replaced with the upper limit value or the lower limit value of a numerical value range of another stage. Furthermore, with regard to a numerical value range described in the present specification, the upper limit value or the lower limit value of the numerical value range may be replaced with a value shown in Examples. Furthermore, separately described upper limit values and lower limit values can be arbitrarily combined. Furthermore, in the present specification, the term “(meth)acrylate” means at least one of acrylate and methacrylate corresponding thereto. The same also applies to other similar expressions such as “(meth)acryloyl”. Furthermore, the term “(poly)” means both a case with the prefix “poly” and a case without the prefix “poly”. Furthermore, the expression “A or B” may include any one of A and B or may include both of them. Furthermore, unless particularly stated otherwise, the materials mentioned below as examples may be used singly, or two or more kinds thereof may be used in combination. Regarding the content of each component in a composition, in a case where a plurality of substances corresponding to each component are present in a composition, unless particularly stated otherwise, the content means the total amount of the plurality of substances present in the composition.

[Semiconductor Device]

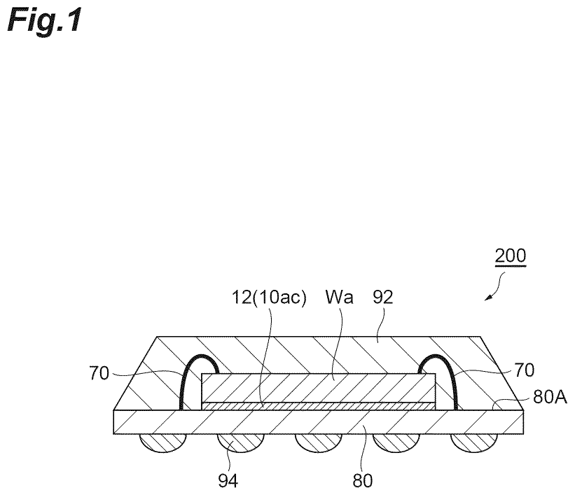

FIG. 1 is a schematic cross-sectional view illustrating an embodiment of a semiconductor device. A semiconductor device 200 shown in FIG. 1 includes: a semiconductor chip Wa; a support member 80 on which the semiconductor chip Wa is mounted; and a bonding adhesive member 12. The bonding adhesive member 12 is provided between the semiconductor chip Wa and the support member 80 and adheres the semiconductor chip Wa and the support member 80. The bonding adhesive member 12 includes a sintered body of silver particles. The bonding adhesive member 12 may be a cured product of an adhesive (composition) including a sintered body of silver particles and may be a cured product of a film-shaped adhesive (cured product 10ac of an adhesive piece) including a sintered body of silver particles. A connection terminal (not shown in the drawing) of the semiconductor chip Wa may be electrically connected to an external connection terminal (not shown in the drawing) by means of a wire 70. The semiconductor chip Wa may be encapsulated by using an encapsulant layer 92 formed from an encapsulant. On a surface of the support member 80 on the opposite side of the surface 80A, solder balls 94 may be formed for electrical connection with an external substrate (motherboard) (not shown in the drawing).

The semiconductor chip Wa (semiconductor element) may be, for example, an IC (integrated circuit) and the like. Examples of the support member 80 include lead frames such as an Alloy 42 lead frame and a copper lead frame; plastic films such as a polyimide resin and an epoxy resin; modified plastic films obtained by impregnating a base material such as a glass nonwoven fabric with a plastic such as a polyimide resin or an epoxy resin and curing the plastic; and ceramics such as alumina.

The semiconductor device 200 has excellent heat dissipation properties. The reason why such an effect is provided is speculated to be that, for example, since the bonding adhesive member 12 includes a sintered body of silver particles, the thermal conductivity of the bonding adhesive member 12 is improved, and the heat dissipation properties of the semiconductor device 200 are improved.

In the following description, a film-shaped adhesive that is suitably used for the manufacture of such a semiconductor device, a method for manufacturing the film-shaped adhesive, a dicing-die bonding integrated film, and a method for manufacturing the dicing-die bonding integrated film will be described in detail.

[Film-Shaped Adhesive]

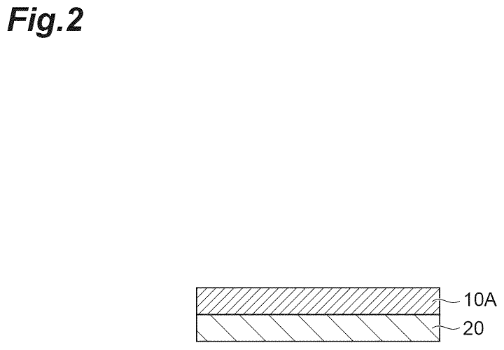

FIG. 2 is a schematic cross-sectional view illustrating an embodiment of a film-shaped adhesive. A film-shaped adhesive 10A shown in FIG. 2 is thermosetting, and the film-shaped adhesive 10A goes through a semi-cured (B-stage) state and enters a completely cured (C-stage) state after a curing treatment. The film-shaped adhesive 10A includes a sintered body of silver particles in the C-stage state (for example, cured product obtainable when thermally cured under the conditions of 170° C. and 3 hours). The film-shaped adhesive 10A may be provided on a support film 20 as shown in FIG. 2. The film-shaped adhesive 10A may be a die bonding film used for the adhesion between a semiconductor chip and a support member or the adhesion between semiconductor chips.

The support film 20 is not particularly limited, and examples thereof include films of polytetrafluoroethylene, polyethylene, polypropylene, polymethylpentene, polyethylene terephthalate, polyimide, and the like. The support film may be subjected to a mold release treatment. The thickness of the support film 20 may be, for example, 10 to 200 μm or 20 to 170 μm.

The film-shaped adhesive 10A contains silver particles (hereinafter, may be referred to as “component (A)”) and a thermosetting resin component (hereinafter, may be referred to as “component (B)”) and may further contain, as necessary, an elastomer (hereinafter, may be referred to as “component (C)”), a coupling agent (hereinafter, may be referred to as “component (D)”), a curing accelerator (hereinafter, may be referred to as “component (E)”), and the like.

Component (A): Silver particles

Silver particles as the component (A) constitute a component for increasing the heat dissipation properties in the film-shaped adhesive. The silver particles may be, for example, particles composed of silver (particles composed of silver alone) or silver-coated metal particles in which the surface of metal particles (copper particles or the like) is coated with silver. Examples of the silver-coated metal particles include silver-coated copper particles. The component (A) may be particles composed of silver.

The silver particles as the component (A) may be silver particles manufactured by a reduction method (silver particles manufactured by a liquid phase (wet type) reduction method using a reducing agent). A film-shaped adhesive obtainable by using such silver particles for the bonding adhesive member (and in addition, performing a predetermined mixing treatment that will be described below for the production of the film-shaped adhesive) may include a sintered body in which the silver particles are sintered together in a cured (C-stage) state after a curing treatment (for example, a state of being thermally cured under the conditions of 170° C. and 3 hours).

With regard to the liquid phase (wet type) reduction method using a reducing agent, a surface treatment agent (lubricating agent) is usually added from the viewpoint of controlling the particle size and preventing aggregation and fusion, and silver particles manufactured by the liquid phase (wet type) reduction method using a reducing agent have the surface coated by the surface treatment agent (lubricating agent). For that reason, the silver particles manufactured by a reduction method may be considered as silver particles that are surface-treated with a surface treatment agent. Examples of the surface treatment agent include fatty acid compounds such as oleic acid (melting point: 13.4° C.), myristic acid (melting point: 54.4° C.), palmitic acid (melting point: 62.9° C.), and stearic acid (melting point: 69.9° C.); fatty acid amide compounds such as oleic acid amide (melting point: 76° C.) and stearic acid amide (melting point: 100° C.); aliphatic alcohol compounds such as pentanol (melting point: −78° C.), hexanol (melting point: −51.6° C.), oleyl alcohol (melting point: 16° C.), and stearyl alcohol (melting point: 59.4° C.); and aliphatic nitrile compounds such as oleanitrile (melting point: −1° C.). The surface treatment agent may be a surface treatment agent having a low melting point (for example, a melting point of 100° C. or lower) and high solubility in organic solvents.

The shape of the silver particles as the component (A) is not particularly limited and may be, for example, a flake shape, a resin shape, a spherical shape, or the like. When the shape of the silver particles is a spherical shape, the surface roughness (Ra) of the film-shaped adhesive tends to be easily ameliorated.

The component (A) may be silver particles having an average particle size of 0.01 to 10 μm. When the average particle size of the silver particles is 0.01 μm or more, effects such as that an increase in viscosity at the time of producing an adhesive varnish can be prevented, that a desired quantity of silver particles can be incorporated into the film-shaped adhesive, and that more satisfactory adhesiveness can be exhibited by securing the wettability of the film-shaped adhesive on an adherend, tend to be provided. When the average particle size of the silver particles is 10 μm or less, there is a tendency that the film molding properties are more excellent, and the heat dissipation properties brought by addition of silver particles can be further improved. Furthermore, as the average particle size of the silver particles is 10 μm or less, there is a tendency that the thickness of the film-shaped adhesive can be made thinner, semiconductor chips can be more highly laminated, and at the same time, the generation of cracks in semiconductor chips caused by protrusion of silver particles from the film-shaped adhesive can be prevented. The average particle size of the silver particles as the component (A) may be 0.1 μm or more, 0.3 μm or more, or 0.5 μm or more and may be 8.0 μm or less, 7.0 μm or less, 6.0 μm or less, 5.0 μm or less, 4.0 μm or less, or 3.0 μm or less.

Incidentally, according to the present specification, the average particle size of the silver particles as the component (A) means the particle size (laser 50% particle size (D₅₀)) when the ratio (volume ratio) of the silver particles as the component (A) with respect to the total volume of silver particles is 50%. The average particle size (D₅₀) can be determined by measuring a suspension obtained by suspending silver particles in water by a laser scattering method using a laser scattering type particle size measuring apparatus (for example, MicroTrac).

The silver particle as the component (A) may be a combination of two or more kinds of silver particles having different shapes or average particles, from the viewpoint that the silver particles are sintered and easily form heat dissipation paths. The combination of the silver particles as the component (A) may be, for example, a combination of silver particles (preferably, spherical-shaped silver particles) having an average particle size of 0.01 μm or more and 1 μm or less and silver particles (preferably, spherical-shaped silver particles) having an average particle size of more than 1 μm and 10 μm or less.

The content of the component (A) may be 50% to 95% by mass based on the total amount of the film-shaped adhesive. When the content of the component (A) is 50% by mass or more based on the total amount of the film-shaped adhesive, there is a tendency that the thermal conductivity of the film-shaped adhesive can be further improved, and the heat dissipation properties of the semiconductor device can be further improved. The content of the component (A) may be 60% by mass or more, 70% by mass or more, 75% by mass or more, or 80% by mass or more, based on the total amount of the film-shaped adhesive. When the content of the component (A) is 95% by mass or less based on the total amount of the film-shaped adhesive, other components can be more sufficiently incorporated into the film-shaped adhesive, and in a case where a dicing-die bonding integrated film is formed, the adhesiveness between the bonding adhesive layer and the pressure-sensitive adhesive layer tends to be more sufficient. The content of the component (A) may be 92% by mass or less, 90% by mass or less, or 88% by mass or less, based on the total amount of the film-shaped adhesive. Incidentally, the content of the component (A) based on the total solid content of the adhesive varnish may be similar to the above-described range.

Component (B): Thermosetting Resin Component

Component (B) may be, for example, a combination of a thermosetting resin (hereinafter, may be referred to as “component (B1)”) and a curing agent (hereinafter, may be referred to as “component (B2)”). Component (B1) is a component having a property of forming three-dimensional bonds between molecules and curing as a result of heating or the like and is a component exhibiting an adhesive action after curing. The component (B1) may be an epoxy resin. Component (B2) may be a phenol resin that can serve as a curing agent for an epoxy resin. The component (B) may include an epoxy resin as the component (B1) and a phenol resin as the component (B2).

(Epoxy Resin)

Regarding the epoxy resin, any resin having epoxy groups in the molecule can be used without particular limitation. The epoxy resin may be a resin having two or more epoxy groups in the molecule. The epoxy resin may include an epoxy resin that is liquid at 25° C.

Examples of the epoxy resin include a bisphenol A type epoxy resin, a bisphenol F type epoxy resin, a bisphenol S type epoxy resin, a phenol novolac type epoxy resin, a cresol novolac type epoxy resin, a bisphenol A novolac type epoxy resin, a bisphenol F novolac type epoxy resin, a stilbene type epoxy resin, a triazine skeleton-containing epoxy resin, a fluorene skeleton-containing epoxy resin, a triphenolmethane type epoxy resin, a biphenyl type epoxy resin, a xylylene type epoxy resin, a biphenylaralkyl type epoxy resin, a naphthalene type epoxy resin, a dicyclopentadiene type epoxy resin, a polyfunctional phenol, and a diglycidyl ether compound of a polycyclic aromatic compound such as anthracene. These may be used singly or in combination of two or more kinds thereof.

The epoxy resin may include an epoxy resin that is liquid at 25° C. There is a tendency that by including such an epoxy resin, the surface roughness (Ra) of the film-shaped adhesive is likely to be ameliorated. Examples of a commercially available product of the epoxy resin that is liquid at 25° C. include EXA-830CRP (trade name, manufactured by DIC Corporation) and YDF-8170 (trade name, NIPPON STEEL Chemical & Material Co., Ltd.).

The epoxy equivalent of the epoxy resin is not particularly limited and may be 90 to 300 g/eq or 110 to 290 g/eq. When the epoxy equivalent of the epoxy resin is in such a range, there is a tendency that the fluidity of an adhesive varnish when forming a film-shaped adhesive is easily secured while maintaining the bulk strength of the film-shaped adhesive.

The content of the component (B1) may be 0.1% by mass or more, 1% by mass or more, 2% by mass or more, or 3% by mass or more, and may be 15% by mass or less, 12% by mass or less, 10% by mass or less, 8% by mass or less, or 6% by mass or less, based on the total amount of the film-shaped adhesive. Incidentally, the content of the component (B1) based on the total solid content of the adhesive varnish may be similar to the above-described range.

When an epoxy resin that is liquid at 25° C. is included as the component (B1), the mass ratio of this epoxy resin with respect to the total amount of the component (B1) (mass of this epoxy resin/total mass of component (B1)) as a percentage may be 10% to 100%, 40% to 100%, 60% to 100%, or 80% to 100%. Incidentally, the mass ratio of this epoxy resin with respect to the total amount of the component (B1) in the adhesive varnish may be similar to the above-described range. When an epoxy resin that is liquid at 25° C. is included as the component (B1), the content of this epoxy resin may be 0.1% by mass or more, 1% by mass or more, 2% by mass or more, or 3% by mass or more, and may be 15% by mass or less, 12% by mass or less, 10% by mass or less, 8% by mass or less, or 6% by mass or less, based on the total amount of the film-shaped adhesive. Incidentally, the content of this epoxy resin based on the total solid content of the adhesive varnish may be similar to the above-described range.

(Phenol Resin)

Regarding the phenol resin, any resin having phenolic hydroxyl groups in the molecule can be used without particular limitation. Examples of the phenol resin include a novolac type phenol resin obtainable by condensing or co-condensing a phenol such as phenol, cresol, resorcin, catechol, bisphenol A, bisphenol F, phenylphenol, or aminophenol, and/or a naphthol such as α-naphthol, β-naphthol, or dihydroxynaphthalene, with a compound having an aldehyde group, such as formaldehyde, in the presence of an acidic catalyst; a phenol aralkyl resin synthesized from a phenol and/or a naphthol, such as allylated bisphenol A, allylated bisphenol F, allylated naphthalenediol, phenol novolac, or phenol, and dimethoxy-para-xylene or bis(methoxymethyl)biphenyl; a naphthol aralkyl resin, a biphenyl aralkyl type phenol resin, and a phenyl aralkyl type phenol resin. These may be used singly or in combination of two or more kinds thereof.

The hydroxyl group equivalent of the phenol resin may be 40 to 300 g/eq, 70 to 290 g/eq, or 100 to 280 g/eq. When the hydroxyl group equivalent of the phenol resin is 40 g/eq or more, the storage modulus of the film tends to be further improved, and when the hydroxyl group equivalent is 300 g/eq or less, it is possible to prevent defects caused by foaming, occurrence of outgassing, and the like.

The ratio of the epoxy equivalent of the epoxy resin as the component (B1) and the hydroxyl group equivalent of the phenol resin as the component (B2) (epoxy equivalent of epoxy resin as component (B1)/hydroxyl group equivalent of phenol resin as component (B2)) may be 0.30/0.70 to 0.70/0.30, 0.35/0.65 to 0.65/0.35, 0.40/0.60 to 0.60/0.40, or 0.45/0.55 to 0.55/0.45, from the viewpoint of curability. When this equivalent ratio is 0.30/0.70 or more, more sufficient curability tends to be obtained. When this equivalent ratio is 0.70/0.30 or less, an excessive increase of viscosity can be prevented, and more sufficient fluidity can be obtained.

The content of the component (B2) may be 0.1% by mass or more, 0.5% by mass or more, 1% by mass or more, or 2% by mass or more, and may be 15% by mass or less, 12% by mass or less, 10% by mass or less, 8% by mass or less, or 6% by mass or less, based on the total amount of the film-shaped adhesive. Incidentally, the content of the component (B2) based on the total solid content of the adhesive varnish may be similar to the above-described range.

The content of the component (B) (total content of component (B1) and component (B2)) may be 0.1% by mass or more, 1% by mass or more, 3% by mass or more, or 5% by mass or more, and may be 30% by mass or less, 25% by mass or less, 20% by mass or less, or 15% by mass or less, based on the total amount of the film-shaped adhesive. Incidentally, the content of the component (B) based on the total solid content of the adhesive varnish may be similar to the above-described range.

Component (C): Elastomer

Examples of component (C) include a polyimide resin, an acrylic resin, a urethane resin, a polyphenylene ether resin, a polyetherimide resin, a phenoxy resin, and a modified polyphenylene ether resin. The component (C) may be one of these resins while being a resin having a crosslinkable functional group or may be an acrylic resin having a crosslinkable functional group. Here, the acrylic resin means a (meth)acrylic (co)polymer including a constituent unit derived from (meth)acrylate ((meth)acrylic acid ester). The acrylic resin may be a (meth)acrylic (co)polymer including a constituent unit derived from a (meth)acrylate having a crosslinkable functional group such as an epoxy group, an alcoholic or phenolic hydroxyl group, or a carboxy group. Furthermore, the acrylic resin may be an acrylic rubber such as a copolymer of (meth)acrylate and acrylonitrile. These elastomers may be used singly or in combination of two or more kinds thereof.

Examples of a commercially available product of the acrylic resin include SG-P3, SG-70L, SG-708-6, WS-023 EK30, SG-280 EK23, HTR-860P-3, HTR-860P-3CSP, and HTR-860P-3CSP-3DB (all manufactured by Nagase ChemteX Corporation).

The glass transition temperature (Tg) of the elastomer as the component (C) may be −50° C. to 50° C. or −30° C. to 20° C. When Tg is −50° C. or higher, since tackiness of the film-shaped adhesive is lowered, handleability tends to be further improved. When Tg is 50° C. or lower, there is a tendency that fluidity of an adhesive varnish when forming the film-shaped adhesive can be more sufficiently secured. Here, the Tg of the elastomer as the component (C) means a value measured by using a DSC (thermal differential scanning calorimeter) (for example, manufactured by Rigaku Corporation, trade name: Thermo Plus 2).

The weight average molecular weight (Mw) of the elastomer as the component (C) may be 50000 to 1600000, 100000 to 1400000, or 300000 to 1200000. When the glass transition temperature of the elastomer as the component (C) is 50000 or more, the film-forming properties tend to be more excellent. When the weight average molecular weight of the component (C) is 1600000 or less, fluidity of an adhesive varnish when forming the film-shaped adhesive tends to be more excellent. Here, the Mw of the elastomer as the component (C) means a value measured by gel permeation chromatography (GPC) and converted by using a calibration curve based on polystyrene standards.

The measuring apparatus, measurement conditions, and the like for the Mw of the elastomer as the component (C) are, for example, as follows.
Pump: L-6000 (manufactured by Hitachi, Ltd.)
Column: A column having Gelpack GL-R440 (manufactured by Hitachi Chemical Company, Ltd.), Gelpack GL-R450 (manufactured by Hitachi Chemical Company, Ltd.), and Gelpack GL-R400M (manufactured by Hitachi Chemical Company, Ltd.) (each 10.7 mm (diameter)×300 mm) connected in this order
Eluent: Tetrahydrofuran (hereinafter, referred to as “THF”)
Sample: Solution obtained by dissolving 120 mg of a sample in 5 mL of THF
Flow rate: 1.75 mL/min

The content of the component (C) may be 0.1% by mass or more, 0.5% by mass or more, 1% by mass or more, 2% by mass or more, or 3% by mass or more, and may be 15% by mass or less, 12% by mass or less, 10% by mass or less, 8% by mass or less, or 6% by mass or less, based on the total amount of the film-shaped adhesive. Incidentally, the content of the component (C) based on the total solid content of the adhesive varnish may be similar to the above-described range.

Component (D): Coupling Agent

Component (D) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl)aminopropyltrimethoxysilane. These may be used singly or in combination of two or more kinds thereof.

Component (E): Curing Accelerator

Examples of component (E) include an imidazole and derivatives thereof, an organophosphorus-based compound, a secondary amine, a tertiary amine, and a quaternary ammonium salt. These may be used singly or in combination of two or more kinds thereof. Among these, from the viewpoint of reactivity, the component (E) may be an imidazole and derivatives thereof.

Examples of the imidazole include 2-methylimidazole, 1-benzyl-2-methylimidazole, 1-cyanoethyl-2-phenylimidazole, and 1-cyanoethyl-2-methylimidazole. These may be used singly or in combination of two or more kinds thereof.

The film-shaped adhesive may further contain other components. Examples of the other components include a pigment, an ion scavenger, and an oxidation inhibitor.

The total content of the component (D), component (E), and other components may be 0.005% to 10% by mass based on the total mass of the film-shaped adhesive. Incidentally, the total content of the component (D), component (E), and other components based on the total solid content of the adhesive varnish may be similar to the above-described range.

The film-shaped adhesive 10A may be a film-shaped adhesive containing component (A) and component (B), which includes a sintered body of silver particles in a cured product of the film-shaped adhesive obtainable when the film-shaped adhesive is thermally cured under the conditions of 170° C. and 3 hours.

[Method for Manufacturing Film-Shaped Adhesive]

The film-shaped adhesive 10A shown in FIG. 2 can be obtained by a manufacturing method including: mixing a raw material varnish containing component (A) and an organic solvent under the temperature conditions of 50° C. or higher and preparing an adhesive varnish containing component (A), an organic solvent, and component (B) (mixing step); and forming a film-shaped adhesive by using the adhesive varnish (formation step). The adhesive varnish may further contain component (C), component (D), component (E), and other components, as necessary.

(Mixing Step)

The mixing step is mixing a raw material varnish containing component (A) and an organic solvent under the temperature conditions of 50° C. or higher and preparing an adhesive varnish containing component (A), an organic solvent, and component (B).

The organic solvent is not particularly limited as long as it can dissolve the components other than the component (A). Examples of the organic solvent include aromatic hydrocarbons such as toluene, xylene, mesitylene, cumene, and p-cymene; aliphatic hydrocarbons such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, γ-butyrolactone, butyl carbitol acetate, and ethyl carbitol acetate; carbonic acid esters such as ethylene carbonate and propylene carbonate; amides such as N,N-dimethylformamide, N,N-dimethylacetamide, and N-methyl-2-pyrrolidone; and alcohols such as butyl carbitol and ethyl carbitol. These may be used singly or in combination of two or more kinds thereof. Among these, from the viewpoints of the solubility of surface treatment agents and the boiling point, the organic solvent may be N,N-dimethylformamide, N,N-dimethylacetamide, N-methyl-2-pyrrolidone, butyl carbitol, ethyl carbitol, butyl carbitol acetate, ethyl carbitol acetate, or cyclohexanone. The solid component concentration in the raw material varnish may be 10% to 80% by mass based on the total mass of the raw material varnish.

The raw material varnish can be obtained by, for example, adding each component into a container that is used with a stirrer. In this case, the order of addition of each component is not particularly limited and can be appropriately set according to the properties of each component.

Mixing can be performed by appropriately combining conventional stirrers such as a homodisper, a three-one motor, a mixing rotor, a planetary, and a Raikai mixer. The stirrers may include a heating facility such as a heater unit capable of managing the temperature conditions for the raw material varnish or the adhesive varnish. When a homodisper is used for mixing, the speed of rotation of the homodisper may be 4000 rotations/min or higher.

The mixing temperature of the mixing step is 50° C. or higher. Regarding the mixing temperature of the mixing step, heating may be performed using a heating facility or the like as necessary. When the mixing temperature of the mixing step is 50° C. or higher, the film-shaped adhesive thus obtained may include a sintered body of silver particles in a cured (C-stage) state after a curing treatment (for example, a cured product obtainable when the film-shaped adhesive is thermally cured under the conditions of 170° C. and 3 hours). Such a phenomenon is exhibited more notably when silver particles manufactured by a reduction method are used as the component (A). The reason why such a phenomenon is exhibited is not necessarily obvious; however, the inventors of the present disclosure presume the reason as follows. Silver particles (manufactured by a liquid phase (wet type) reduction method using a reducing agent) as the component (A) usually have the surface coated with a surface treatment agent (lubricating agent). Here, it is speculated that when the mixing temperature of the mixing step is 50° C. or higher, the surface treatment agent covering the silver particles is dissociated (being in a reduced state), and the silver surface is likely to be exposed. In addition, since such silver particles with exposed silver surface are likely to come into direct contact with each other, it is speculated that when the silver particles are heated under the conditions that cure the film-shaped adhesive, the silver particles are sintered together and easily form a sintered body of the silver particles. As a result, it is conceived that the film-shaped adhesive includes a sintered body of silver particles in a cured (C-stage) state after the curing treatment. Incidentally, silver particles manufactured by an atomization method are known as the component (A). Silver particles manufactured by an atomization method are covered with a silver oxide film on the surface of the silver particles due to the characteristics of the manufacturing method therefor. According to an investigation of the inventors of the present disclosure, it was confirmed that in a case where silver particles manufactured by an atomization method are used, even when the mixing temperature of the mixing step is 50° C. or higher, the film-shaped adhesive thus obtained is less likely to include a sintered body of silver particles in a cured (C-stage) state after a curing treatment. The mixing temperature of the mixing step may be 55° C. or higher, 60° C. or higher, 65° C. or higher, or 70° C. or higher. The upper limit of the mixing temperature of the mixing step may be, for example, 120° C. or lower, 100° C. or lower, or 80° C. or lower. The mixing time of the mixing step may be, for example, 1 minute or more, 5 minutes or more, or 10 minutes or more and may be 60 minutes or less, 40 minutes or less, or 20 minutes or less.

The component (B), component (C), component (D), component (E), or other components can be incorporated into the adhesive varnish in any stage according to the properties of each component. These components may be incorporated into the adhesive varnish by, for example, adding the components to the raw material varnish before the mixing step or may be incorporated by adding the components to the adhesive varnish after the mixing step. It is preferable that the component (D) and component (E) are incorporated by adding the components to the adhesive varnish after the mixing step. In a case where the components are added to the adhesive varnish after the mixing step, the components may be mixed after addition under, for example, temperature conditions of below 50° C. (for example, room temperature (25° C.)). The mixing conditions in this case may be 0.1 to 48 hours at room temperature (25° C.).

In this manner, an adhesive varnish containing the component (A), an organic solvent, and the component (B) can be prepared. With regard to the adhesive varnish, gas bubbles in the varnish may be removed by means of vacuum degassing or the like after preparation.

The solid component concentration in the adhesive varnish may be 10% to 80% by mass based on the total mass of the adhesive varnish.

(Formation Step)

The formation step is forming a film-shaped adhesive by using the adhesive varnish. Examples of a method for forming a film-shaped adhesive include a method of applying the adhesive varnish on a support film.

Regarding the method of applying the adhesive varnish on a support film, a known method can be used, and examples include a knife coating method, a roll coating method, a spray coating method, a gravure coating method, a bar coating method, and a curtain coating method.

After the adhesive varnish is applied on the support film, the organic solvent may be heated and dried as necessary. Heating and drying are not particularly limited as long as the processes are carried out under the conditions in which the organic solvent used is sufficiently volatilized; however, for example, the heating and drying temperature may be 50° C. to 200° C., and the heating and drying time may be 0.1 to 30 minutes. Heating and drying may be carried out stepwise at different heating and drying temperatures or heating and drying times.

In this manner, the film-shaped adhesive 10A can be obtained. The thickness of the film-shaped adhesive 10A can be appropriately adjusted according to the use application; however, for example, the thickness may be 3 μm or more, 5 μm or more, or 10 μm or more, and may be 200 μm or less, 100 μm or less, 50 μm or less, or 30 μm or less.

With regard to a cured product obtainable when the film-shaped adhesive 10A is thermally cured under the conditions of 170° C. and 3 hours, the thermal conductivity (25° C.±1° C.) may be 5.0 W/m·K or higher. When the thermal conductivity is 5.0 W/m·K or higher, the heat dissipation properties of the semiconductor device tend to be more excellent. The thermal conductivity may be 5.2 W/m·K or higher, 5.4 W/m·K or higher, 5.6 W/m·K or higher, 5.8 W/m·K or higher, or 6.0 W/m·K or higher. The upper limit of the thermal conductivity (25° C.±1° C.) is not particularly limited; however, the upper limit may be 30 W/m·K or lower. Incidentally, according to the present specification, the thermal conductivity means a value calculated by the method described in the Examples.

[Dicing-Die Bonding Integrated Film and Method for Manufacturing the Same]

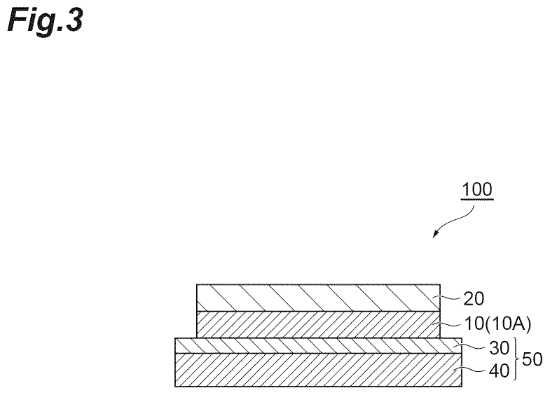

FIG. 3 is a schematic cross-sectional view illustrating an embodiment of a dicing-die bonding integrated film. A dicing-die bonding integrated film 100 shown in FIG. 3 includes a base material layer 40, a pressure-sensitive adhesive layer 30, and a bonding adhesive layer 10 formed from the film-shaped adhesive 10A, in this order. The dicing-die bonding integrated film 100 can also be one that is said to include a dicing tape 50 including a base material layer 40 and a pressure-sensitive adhesive layer 30 provided on the base material layer 40; and a bonding adhesive layer 10 provided on the pressure-sensitive adhesive layer 30 of the dicing tape 50. The dicing-die bonding integrated film 100 may have a film shape, a sheet shape, a tape shape, or the like. The dicing-die bonding integrated film 100 may include a support film 20 on a surface of the bonding adhesive layer 10, the surface being on the opposite side of the pressure-sensitive adhesive layer 30.

Examples of the base material layer 40 in the dicing tape 50 include plastic films such as a polytetrafluoroethylene film, a polyethylene terephthalate film, a polyethylene film, a polypropylene film, a polymethylpentene film, and a polyimide film. Furthermore, the base material layer 40 may be subjected to a surface treatment such as primer application, a UV treatment, a corona discharge treatment, a polishing treatment, or an etching treatment, as necessary.

The pressure-sensitive adhesive layer 30 in the dicing tape 50 is not particularly limited as long as the pressure-sensitive adhesive layer has an adhesive strength that is sufficient not to allow scattering of semiconductor chips at the time of dicing and an adhesive strength that is low to the extent that semiconductor chips are not damaged in the subsequent step of picking up the semiconductor chips, and pressure-sensitive adhesive layers which are conventionally known in the field of dicing tapes can be used. The pressure-sensitive adhesive layer 30 may be a non-ultraviolet curable pressure-sensitive adhesive layer formed from a non-ultraviolet curable pressure-sensitive adhesive or may be an ultraviolet curable pressure-sensitive adhesive layer formed from an ultraviolet curable pressure-sensitive adhesive. When the pressure-sensitive adhesive layer is an ultraviolet curable pressure-sensitive adhesive layer formed from an ultraviolet curable pressure-sensitive adhesive, the adhesiveness of the pressure-sensitive adhesive layer can be lowered by irradiating the pressure-sensitive adhesive layer with ultraviolet radiation.

The thickness of the dicing tape 50 (base material layer 40 and pressure-sensitive adhesive layer 30) may be 60 to 150 μm or 70 to 130 μm from the viewpoints of economic efficiency and film handleability.

The dicing-die bonding integrated film 100 shown in FIG. 3 can be obtained by a manufacturing method including: preparing a film-shaped adhesive 10A that is obtained by the above-described manufacturing method and a dicing tape 50 including a base material layer 40 and a pressure-sensitive adhesive layer 30 provided on the base material layer 40; and sticking together the film-shaped adhesive 10A and the pressure-sensitive adhesive layer 30 of the dicing tape 50. Regarding the method of sticking together the film-shaped adhesive 10A and the pressure-sensitive adhesive layer 30 of the dicing tape 50, a known method can be used.

[Method for Manufacturing Semiconductor Device]

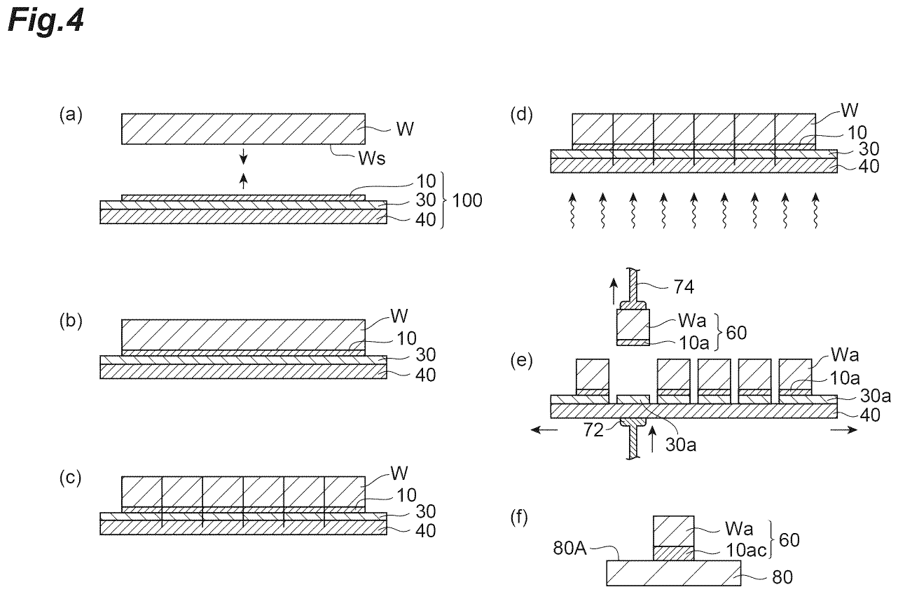

FIG. 4 is schematic cross-sectional views illustrating an embodiment of a method for manufacturing a semiconductor device. FIGS. 4(a), 4(b), 4(c), 4(d), 4(e), and 4(f) are cross-sectional views schematically illustrating each step. The method for manufacturing a semiconductor device includes sticking a semiconductor wafer W to the bonding adhesive layer 10 of the above-described dicing-die bonding integrated film 100 (wafer lamination step, see FIGS. 4(a) and 4(b)); producing a plurality of singulated adhesive piece-attached semiconductor chips 60 by dicing the semiconductor wafer W with the bonding adhesive layer 10 stuck thereto (dicing step, see FIG. 4(c)); adhering an adhesive piece-attached semiconductor chip 60 to a support member 80, with the adhesive piece 10a interposed therebetween (semiconductor chip adhesion step, see FIG. 4(f)); and thermally curing the adhesive piece 10a in the adhesive piece-attached semiconductor chip 60 adhered to the support member 80 (thermal curing step). The method for manufacturing a semiconductor device may further include, as necessary: irradiating the pressure-sensitive adhesive layer 30 with ultraviolet radiation (through the base material layer 40) (ultraviolet irradiation step, see FIG. 4(d)); and picking up a semiconductor chip Wa with an adhesive piece 10a attached thereto (adhesive piece-attached semiconductor chip 60) from the pressure-sensitive adhesive layer 30a (pickup step, see FIG. 4(e)), between the dicing step and the semiconductor chip adhesion step.

<Wafer Lamination Step>

In the present step, first, the dicing-die bonding integrated film 100 is disposed in a predetermined apparatus. Subsequently, the surface Ws of a semiconductor wafer W is stuck to the bonding adhesive layer 10 of the dicing-die bonding integrated film 100 (see FIGS. 4(a) and 4(b)). The circuit surface of the semiconductor wafer W may be provided on the surface on the opposite side of the surface Ws.

Examples of the semiconductor wafer W include single crystal silicon, polycrystal silicon, various ceramics, and compound semiconductors such as gallium arsenide.

<Dicing Step>

In the present step, the semiconductor wafer W and the bonding adhesive layer 10 are diced to be singulated (see FIG. 4(c)). At this time, a portion of the pressure-sensitive adhesive layer 30, or the entirety of the pressure-sensitive adhesive layer 30 and a portion of the base material layer 40 may be diced to be singulated. In this manner, the dicing-die bonding integrated film 100 also functions as a dicing sheet.

<Ultraviolet Irradiation Step>

When the pressure-sensitive adhesive layer 30 is an ultraviolet-curable adhesive layer, the method for manufacturing a semiconductor device may include an ultraviolet irradiation step. In the present step, the pressure-sensitive adhesive layer 30 is irradiated with ultraviolet radiation (through the base material layer 40) (see FIG. 4(d)). With regard to the ultraviolet irradiation, the wavelength of the ultraviolet radiation may be 200 to 400 nm. With regard to the conditions for ultraviolet irradiation, the illuminance and the amount of irradiation may be in the range of 30 to 240 mW/cm² and in the range of 50 to 500 mJ/cm², respectively.

<Pickup Step>

In the present step, while the singulated adhesive piece-attached semiconductor chips 60 are separated apart from each other by expanding the base material layer 40, the adhesive piece-attached semiconductor chips 60 that have been thrusted up by a needle 72 from the base material layer 40 side are sucked by a suction collet 74 and picked up from the pressure-sensitive adhesive layer 30a (see FIG. 4(e)). Incidentally, an adhesive piece-attached semiconductor chip 60 has a semiconductor chip Wa and an adhesive piece 10a. The semiconductor chip Wa is obtained by singulating the semiconductor wafer W, and the adhesive piece 10a is obtained by singulating the bonding adhesive layer 10. Furthermore, the pressure-sensitive adhesive layer 30a is obtained by singulating the pressure-sensitive adhesive layer 30. The pressure-sensitive adhesive layer 30a may remain on the base material layer 40 after the adhesive piece-attached semiconductor chip 60 is picked up. In the present step, it is not necessarily essential to expand the base material layer 40; however, the pickup properties can be further improved by expanding the base material layer 40.

The thrust-up quantity exerted by the needle 72 can be set as appropriate. In addition, from the viewpoint of securing sufficient pickup properties even for an ultrathin wafer, for example, two stages or three stages of thrust-up may be performed. Furthermore, the adhesive piece-attached semiconductor chips 60 may be picked by a method other than the method of using a suction collet 74.

<Semiconductor Chip Adhesion Step>

In the present step, an adhesive piece-attached semiconductor chip 60 thus picked up is adhered to a support member 80 by thermal compression, with the adhesive piece 10a interposed therebetween (see FIG. 4(f)). A plurality of adhesive piece-attached semiconductor chips 60 may be adhered to the support member 80.

The heating temperature for the thermal compression may be, for example, 80° C. to 160° C. The load for the thermal compression may be, for example, 5 to 15 N. The heating time for the thermal compression may be, for example, 0.5 to 20 seconds.

<Thermal Curing Step>

In the present step, the adhesive piece 10a in the adhesive piece-attached semiconductor chip 60 adhered to the support member 80 is thermally cured. By (further) thermally curing the adhesive piece 10a adhering the semiconductor chip Wa and the support member 80, or a cured product 10ac of the adhesive piece, stronger adhesive fixation is enabled. Furthermore, there is a tendency that a sintered body of the silver particles is even more easily obtained by (further) thermally curing the adhesive piece 10a or a cured product 10ac of the adhesive piece. In the case of performing thermal curing, curing may be carried out by simultaneously applying pressure. The heating temperature in the present step can be changed as appropriate depending on the constituent components of the adhesive piece 10a. The heating temperature may be, for example, 60° C. to 200° C. or may be 90° C. to 190° C. or 120° C. to 180° C. The heating time may be 30 minutes to 5 hours or may be 1 to 3 hours or 2 to 3 hours. Incidentally, the heating may be carried out while changing the temperature or pressure stepwise.

The adhesive piece 10a is thermally cured by going through the semiconductor chip adhesion step or the thermal curing step and thereby includes a sintered body of silver particles. The adhesive piece 10a may become a cured product 10ac of an adhesive piece including a sintered body of silver particles. Therefore, the semiconductor device thus obtained may have excellent heat dissipation properties.

The method for manufacturing a semiconductor device may include, as necessary, electrically connecting a tip of a terminal part (inner lead) of the support member and an electrode pad on a semiconductor element by using a bonding wire (wire bonding step). As the bonding wire, for example, a gold wire, an aluminum wire, a copper wire, and the like are used. The temperature at the time of performing wire bonding may be in the range of 80° C. to 250° C. or 80° C. to 220° C. The heating time may be several seconds to several minutes. Wire bonding may be carried out in a state of being heated within the above-described temperature range, by using the vibration energy of ultrasonic waves and the pressure-bonding energy of applied pressure in combination.

The method for manufacturing a semiconductor device may include, as necessary, encapsulating semiconductor elements by using an encapsulant (encapsulation step). The present step is carried out in order to protect the semiconductor elements or bonding wires mounted on the support member. The present step can be carried out by molding a resin for encapsulation (encapsulation resin) in a mold. The encapsulation resin may be, for example, an epoxy-based resin. Due to the heat and pressure during encapsulation, the support member and residue are embedded, and detachment caused by gas bubbles at the adhesive interface can be prevented.

The method for manufacturing a semiconductor device may include, as necessary, curing the encapsulation resin that is insufficiently cured in the encapsulation step (post-curing step). Even in a case where the adhesive piece is not thermally cured in the encapsulation step, the adhesive piece is thermally cured together with curing of the encapsulation resin to enable adhesive fixation in the present step. The heating temperature for the present step can be appropriately set according to the type of the encapsulation resin, and for example, the heating temperature may be in the range of 165° C. to 185° C., while the heating time may be about 0.5 to 8 hours.

The method for manufacturing a semiconductor device may include, as necessary, heating the adhesive piece-attached semiconductor device adhered to the support member by using a reflow furnace (heating and melting step). In the present step, the resin-encapsulated semiconductor device may be surface-mounted on a support member. Examples of the method for surface mounting include reflow soldering of supplying solder in advance onto a printed wiring board, and then heating and melting solder by means of hot air or the like to perform soldering. Examples of the heating method include hot air reflow and infrared reflow. Furthermore, the heating method may be a method of heating the entirety or may be a method of locally heating. The heating temperature may be, for example, in the range of 240° C. to 280° C.

### EXAMPLES

Hereinafter, the present disclosure will be specifically described based on Examples; however, the present disclosure is not intended to be limited to these.

### Examples 1 to 3 and Comparative Examples 1 and 2

<Preparation of Adhesive Varnish>

A raw material varnish was prepared by adding cyclohexanone as an organic solvent to component (A), component (B), and component (C) with the reference symbols and composition ratios (unit: parts by mass) indicated in Table 1. This raw material varnish was stirred for 20 minutes at a rate of 4000 rotations/minute by using a homodisper (manufactured by Tajima-K.K., T.K. HOMO MIXER MARK II) while adjusting the temperature to be the mixing temperature indicated in Table 1, and an adhesive varnish was obtained. Next, the adhesive varnish was left to stand until the temperature reached 20° C. to 30° C., subsequently component (D) and component (E) were added to the adhesive varnish, and the mixture was stirred overnight at a rate of 250 rotations/minute by using a three-one motor. In this manner, adhesive varnishes of Examples 1 to 3 and Comparative Examples 1 and 2, each having a solid content of 610% by mass, were prepared.

Incidentally, the reference symbol of each component in Table 1 means the following.

Component (A): Silver Particles

(A-1) AG-5-1F (trade name, manufactured by DOWA Electronics Materials Co., Ltd., silver particles manufactured by a reduction method, shape: spherical, average particle size (laser 50% particle size (D₅₀)): 2.9 μm)

(A-2) AG-4-1F (trade name, manufactured by DOWA Electronics Materials Co., Ltd., silver particles manufactured by a reduction method, shape: spherical, average particle size (laser 50% particle size (D₅₀)): 2.5 μm)

(A-3) AG-3-1F (trade name, manufactured by DOWA Electronics Materials Co., Ltd., silver particles manufactured by a reduction method, shape: spherical, average particle size (laser 50% particle size (D₅₀)): 1.5 μm)

(A-4) AG-2-1C (trade name, manufactured by DOWA Electronics Materials Co., Ltd., silver particles manufactured by a reduction method, shape: spherical, average particle size (laser 50% particle size (D₅₀)): 0.7 μm)

(A-5) Ag-HWQ (trade name, Fukuda Metal Foil & Powder Co., Ltd., silver particles manufactured by an atomization method, shape: spherical, average particle size (laser 50% particle size (D₅₀)): 1.5 μm)

Component (B): Thermosetting Resin Component

Component (B1): Thermosetting Resin

(B1-1) EXA-830CRP (trade name, manufactured by DIC Corporation, bisphenol F type epoxy resin, epoxy equivalent: 159 g/eq, liquid at 25° C.)

Component (B2): Curing Agent

(B2-1) MEH-7800M (trade name, manufactured by Meiwa Plastic Industries, Ltd., phenol resin, hydroxyl group equivalent: 175 g/eq)

Component (C): Elastomer

(C-1) SG-P3 (trade name, manufactured by Nagase ChemteX Corporation, acrylic rubber, weight average molecular weight: 800000, Tg: −7° C.)

Component (D): Coupling Agent

(D-1) A-1160 (trade name, manufactured by GE Toshiba Silicones Co., Ltd., γ-ureidopropyltriethoxysilane)

Component (E): Curing Accelerator

(E-1) 2PZ-CN (trade name, manufactured by SHIKOKU CHEMICALS CORPORATION, 1-cyanoethyl-2-phenylimidazole)

<Production of Film-Shaped Adhesive>

Film-shaped adhesives were produced by using the adhesive varnishes of Examples 1 to 3 and Comparative Examples 1 and 2. Each adhesive varnish was subjected to vacuum degassing, and the adhesive varnish obtained thereafter was applied on a polyethylene terephthalate (PET) film (thickness: 38 μm) that had been a mold release treatment, which was a support film. The applied adhesive varnish was heated and dried in two stages for 5 minutes at 90° C. and subsequently for 5 minutes at 130° C., and thus, the film-shaped adhesives of Examples 1 to 3 and Comparative Examples 1 and 2, which had a thickness of 20 μm and were in the B-stage state, were obtained on the support film.

<Measurement of Thermal Conductivity>

(Production of Film for Thermal Conductivity Measurement)

A plurality of sheets of each of the film-shaped adhesives of Examples 1 to 3 and Comparative Examples 1 and 2 was stuck together using a rubber roll to produce a laminated film having a thickness of 200 μm or more. Next, the laminated film was cut out into a size of 1 cm×1 cm, and the cut laminated film was thermally cured in a clean oven (manufactured by ESPEC CORP.) at 170° C. for 3 hours to obtain a film for thermal conductivity measurement in the C-stage state.

(Calculation of Thermal Conductivity)

The thermal conductivity λ in the thickness direction of the film for thermal conductivity measurement was calculated by the following formula. The results are shown in Table 1.

Thermal conductivity λ (W/m·K)=Thermal diffusivity α (m²/s)×specific heat Cp (J/kg·K)×density ρ (g/cm³)

Incidentally, the thermal diffusivity α, specific heat Cp, and density ρ were measured by the following methods. A higher thermal conductivity λ means that the semiconductor device has more excellent heat dissipation properties.

(Measurement of Thermal Diffusivity α)

A measurement sample was produced by subjecting both surfaces of the film for thermal conductivity measurement to a blackening treatment using a graphite spray. For the measurement sample, the thermal diffusivity α of the film for thermal conductivity measurement was determined by a laser flash method (xenon flash method) under the following conditions by using the following measuring apparatus.
Measuring apparatus: Thermal diffusivity measuring apparatus (manufactured by NETZSCH Japan K.K., trade name: LFA447 nanoflash)
Pulse width of pulsed light irradiation: 0.1 ms
Applied voltage of pulsed light irradiation: 236 V
Treatment of measurement sample: Blackening treatment of both surfaces of film for thermal conductivity measurement with graphite spray
Measurement ambient temperature: 25° C.±1° C.

(Measurement of Specific Heat Cp (25° C.))

The specific heat Cp (25° C.) of the film for thermal conductivity measurement was determined by performing differential scanning calorimetry (DSC) under the following conditions by using the following measuring apparatus.
Measuring apparatus: Differential scanning calorimetric apparatus (manufactured by PerkinElmer, Inc., trade name: Pyris1)
Reference substance: Sapphire
Temperature increase rate: 10° C./min
Temperature range for temperature increase: room temperature (25° C.) to 60° C.

(Measurement of Density ρ)

The density ρ of the film for thermal conductivity measurement was measured by the Archimedes method under the following conditions by using the following measuring apparatus.
Measuring apparatus: Electronic gravimeter (manufactured by Alfa Mirage Co., Ltd., trade name: SD200L)
Water temperature: 25° C.

<Photographing with Scanning Electron Microscope (SEM)>

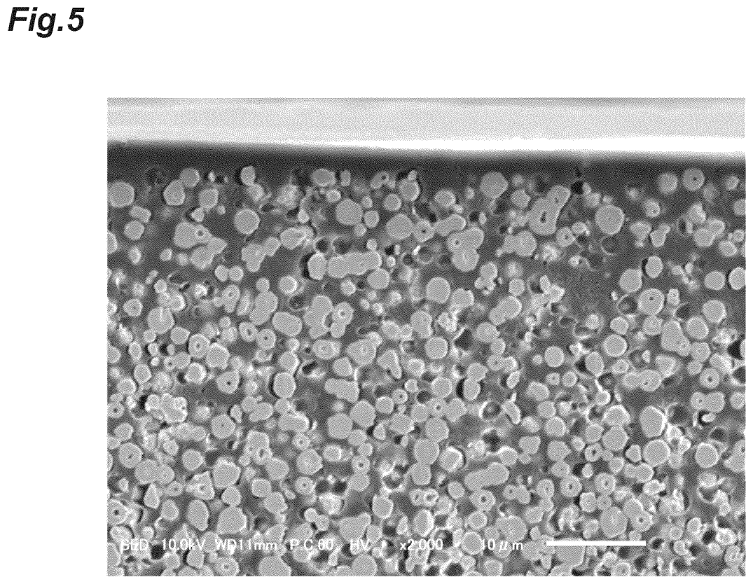

The film-shaped adhesive in the C-stage state of Example 1 was cut along the thickness direction by using a microtome (manufactured by Nihon Microtome Laboratory, Inc., trade name: RMS), and an image of the cross-section was photographed by using a scanning electron microscope (SEM). Regarding a sample for photographing, a sample for photographing in the C-stage state was obtained in the same manner as in the production of the film for thermal conductivity measurement, by sticking together a plurality of sheets of the film-shaped adhesive of Example 1 using a rubber roll to produce a laminated film having a thickness of 200 μm or more and thermally curing the laminated film in a clean oven (manufactured by ESPEC CORP.) at 170° C. for 3 hours. FIG. 5 is an image of a cross-section cut along the thickness direction of the film-shaped adhesive in the C-stage state of Example 1, which was photographed by using a scanning electron microscope (SEM). As shown in FIG. 5, it was confirmed that in the film-shaped adhesive in the C-stage state of Example 1, silver particles were sintered together to form a sintered body.

TABLE 1

| | | | | | | Comp. | Comp. |
|---|---|---|---|---|---|---|---|
| | | | Exam. 1 | Exam. 2 | Exam. 3 | Exam. 1 | Exam. 2 |
| (A) | | (A-1) | 65 | — | — | 65 | — |
| | | (A-2) | — | 65 | — | — | — |
| | | (A-3) | — | — | 65 | — | — |
| | | (A-4) | 19 | 19 | 19 | 19 | — |
| | | (A-5) | — | — | — | — | 84 |
| (B) | (B1) | (B1-1) | 5.9 | 5.9 | 5.9 | 5.9 | 5.9 |
| | (B2) | (B2-1) | 4.7 | 4.7 | 4.7 | 4.7 | 4.7 |

| | | | | | | |
|---|---|---|---|---|---|---|
| (C) | (C-1) | 5.3 | 5.3 | 5.3 | 5.3 | 5.3 |
| (D) | (D-1) | 0.03 | 0.03 | 0.03 | 0.03 | 0.03 |
| (E) | (E-1) | 0.01 | 0.01 | 0.01 | 0.01 | 0.01 |

| | | | | | |
|---|---|---|---|---|---|
| Mixing temperature | 70 | 70 | 70 | 30 | 30 |
| (° C.) | | | | | |
| Thermal conductivity | 6.2 | 6.4 | 5.6 | 2.5 | 0.9 |
| (W/m · K) | | | | | |

As shown in Table 1, the film-shaped adhesives of Examples 1 to 3 obtained by using predetermined silver particles and mixing under predetermined mixing temperature conditions had excellent thermal conductivity in the C-stage state (cured product obtainable when the film-shaped adhesive was thermally cured under the conditions of 170° C. and 3 hours). Furthermore, as shown in FIG. 5, it was confirmed that in the film-shaped adhesive of Example 1, a sintered body of silver particles was formed in the C-stage state. It is speculated that in the film-shaped adhesives of Examples 2 and 3 obtained by a similar manufacturing method, a sintered body of silver particles was formed in the C-stage state. On the other hand, as shown in Comparative Examples 1 and 2, it was confirmed that when mixing was not achieved under predetermined mixing temperature conditions, the thermal conductivity was not sufficient in the C-stage state.

From the above-described results, it was confirmed that the film-shaped adhesive of the present disclosure has a high thermal conductivity in the C-stage state (cured product obtainable when the film-shaped adhesive is thermally cured under the conditions of 170° C. and 3 hours) and exhibits high heat dissipation properties. The semiconductor device has a bonding adhesive member including a sintered body of silver particles. Therefore, it can be expected that the semiconductor device thus obtained has excellent heat dissipation properties.

### REFERENCE SIGNS LIST

10: bonding adhesive layer, 10A: film-shaped adhesive, 10a: adhesive piece, 10ac: cured product of adhesive piece, 12: bonding adhesive member, 20: support film, 30, 30a: pressure-sensitive adhesive layer, 40: base material layer, 50: dicing tape, 60: adhesive piece-attached semiconductor chip, 70: wire, 72: needle, 74: suction collet, 80: support member, 92: encapsulant layer, 94: solder ball, 100: dicing-die bonding integrated film, 200: semiconductor device, W: semiconductor wafer, Wa: semiconductor chip.

1. A semiconductor device comprising:
a semiconductor chip;
a support member having the semiconductor chip mounted thereon; and
a bonding adhesive member provided between the semiconductor chip and the support member and adhering the semiconductor chip and the support member,
wherein the bonding adhesive member comprising a sintered body of silver particles.

2. A method for manufacturing a film-shaped adhesive, the method comprising:
mixing a raw material varnish comprising silver particles and an organic solvent under temperature conditions of 50° C. or higher and preparing an adhesive varnish comprising the silver particles, the organic solvent, and a thermosetting resin component; and
forming the film-shaped adhesive by using the adhesive varnish.

3. The method for manufacturing a film-shaped adhesive according to claim 2, wherein the silver particles are silver particles manufactured by a reduction method.

4. The method for manufacturing a film-shaped adhesive according to claim 2, wherein the silver particles are silver particles that are surface-treated by using a surface treatment agent.

5. The method for manufacturing a film-shaped adhesive according to claim 2, wherein a content of the silver particles is 50% to 95% by mass based on a total solid content of the adhesive varnish.

6. The method for manufacturing a film-shaped adhesive according to claim 2, wherein the adhesive varnish further contains an elastomer.

7. The method for manufacturing a film-shaped adhesive according to claim 2, wherein the thermosetting resin component includes an epoxy resin and a phenol resin.

8. A method for manufacturing a dicing-die bonding integrated film, the method comprising:
preparing the film-shaped adhesive obtainable by the method according to claim 2, and a dicing tape comprising a base material layer and a pressure-sensitive adhesive layer provided on the base material layer; and
sticking together the film-shaped adhesive and the pressure-sensitive adhesive layer of the dicing tape to form a dicing-die bonding integrated film including the base material layer, the pressure-sensitive adhesive layer, and a bonding adhesive layer formed from the film-shaped adhesive, in this order.

9. A method for manufacturing a semiconductor device, the method comprising:
sticking a semiconductor wafer to the bonding adhesive layer of the dicing-die bonding integrated film obtainable by the method according to claim 8;
producing a plurality of singulated adhesive piece-attached semiconductor chips by dicing the semiconductor wafer with the bonding adhesive layer stuck thereto;
adhering the adhesive piece-attached semiconductor chips on a support member, with the adhesive piece interposed therebetween; and
thermally curing the adhesive piece in the adhesive piece-attached semiconductor chip adhered to the support member.

10. A film-shaped adhesive comprising a sintered body of silver particles in a cured product obtainable when the film-shaped adhesive is thermally cured under conditions of 170° C. and 3 hours.

11. The film-shaped adhesive according to claim 10, wherein the cured product obtainable when the film-shaped adhesive is thermally cured under conditions of 170° C. and 3 hours has a thermal conductivity of 5.0 W/m·K or higher.

12. The film-shaped adhesive according to claim 10, wherein a content of the silver particles is 50% to 95% by mass based on a total amount of the film-shaped adhesive.

13. A dicing-die bonding integrated film comprising a base material layer, a pressure-sensitive adhesive layer, and a bonding adhesive layer formed from the film-shaped adhesive according to claim 10.
